(19) United States
(12) Patent Application Publication
(10) Pub. No.: US 2004/0031519 A1
(43) Pub. Date: Feb. 19, 2004

(54) Nano-porous metal oxide semiconductor spectrally sensitized with metal oxide chalcogenide nano-particles

(75) Inventor: Hieronymus Andriessen, Beerse (BE)

Correspondence Address: LEYDIG VOIT & MAYER, LTD, TWO PRUDENTIAL PLAZA, SUITE 4900, 180 NORTH STETSON AVENUE, CHICAGO, IL, 60601-6780, US

(73) Assignee: AGFA-GEVAERT, Mortsel (BE)

(21) Appl. No.: 10/628,618

(22) Filed: Jul. 28, 2003

Related U.S. Application Data
(60) Provisional application No. 60/406,000, filed on Aug. 26, 2002.

(30) Foreign Application Priority Data
Aug. 13, 2002 (EP) 02102130.8

(51) Int. Cl. H01L 31/00; B32B 9/00

(52) U.S. Cl. 136/252; 428/689

(57) ABSTRACT

A nano-porous metal oxide semiconductor with a band-gap of greater than 2.9 eV in-situ spectrally sensitized on its internal and external surface with metal chalcogenide nano-particles with a bandgap of less than 2.9 eV containing at least one metal chalcogenide, wherein the nano-porous metal oxide further contains a phosphoric acid or a phosphate; and a process for in-situ spectral sensitization of nano-porous metal oxide semiconductor with a band-gap of greater than 2.9 eV on its internal and external surface with metal chalcogenide nano-particles with a band-gap of less than 2.9 eV, containing at least one metal chalcogenide, comprising a metal chalcogenide-forming cycle comprising the steps of: contacting nano-porous metal oxide with a solution of metal ions; contacting nano-porous metal oxide with a solution of chalcogenide ions; and subsequent to metal chalcogenide formation rinsing the nano-porous metal oxide with an aqueous solution containing a phosphoric acid or a phosphate.

### CROSS-REFERENCE TO RELATED PATENT APPLICATIONS

This application claims the benefit of U.S. Provisional Application No. 60/406,000 filed Aug. 26, 2002, which is incorporated by reference. In addition, this application claims the benefit of European Application No. 02102130.8 filed Aug. 13, 2002, which is also incorporated by reference.

### FIELD OF THE INVENTION

The present invention relates to a nano-porous metal oxide semiconductor in-situ spectrally sensitized with metal chalcogenide.

### BACKGROUND OF THE INVENTION

There are two basic types of photoelectrochemical photovoltaic cells. The first type is the regenerative cell which converts light to electrical power leaving no net chemical change behind. Photons of energy exceeding that of the band gap generate electron-hole pairs, which are separated by the electrical field present in the space-charge layer. The negative charge carriers move through the bulk of the semiconductor to the current collector and the external circuit. The positive holes (h⁺) are driven to the surface where they are scavenged by the reduced form of the redox relay molecular (R), oxidizing it: h⁺+R→O, the oxidized form. 0 is reduced back to R by the electrons that re-enter the cell from the external circuit. In the second type, photosynthetic cells, operate on a similar principle except that there are two redox systems: one reacting with the holes at the surface of the semiconductor electrode and the second reacting with the electrons entering the counter-electrode. In such cells water is typically oxidized to oxygen at the semiconductor photoanode and reduced to hydrogen at the cathode. Titanium dioxide has been the favoured semiconductor for these studies. Unfortunately because of its large band-gap (3 to 3.2 eV), TiO₂ absorbs only part of the solar emission and so has low conversion efficiencies. Graetzel reported in 2001 in Nature, volume 414, page 338, that numerous attempts to shift the spectral response of TiO₂ into the visible had so far failed.

Mesoscopic or nano-porous semiconductor materials, minutely structured materials with an enormous internal surface area, have been developed for the first type of cell to improve the light capturing efficiency by increasing the area upon which the spectrally sensitizing species could adsorb. Arrays of nano-crystals of oxides such as TiO₂, ZnO, SnO₂ and Nb₂O₅ or chalcogenides such as CdSe are the preferred semiconductor materials and are interconnected to allow electrical conduction to take place. A wet type solar cell having a nano-porous film of dye-sensitized titanium dioxide semiconductor particles as a work electrode was expected to surpass an amorphous silicon solar cell in conversion efficiency and cost. These fundamental techniques were disclosed in 1991 by Graetzel et al. in Nature, volume 353, pages 737-740 and in U.S. Pat. No. 4,927,721, U.S. Pat. No. 5,350,644 and JP-A 05-504023. Graetzel et al. reported solid-state dye-sensitized mesoporous TiO₂ solar cells with up to 33% photon to electron conversion efficiences.

In 1995 Tennakone et al. in Semiconductor Sci. Technol., volume 10, page 1689 and O'Regan et al. in Chem. Mater., volume 7, page 1349 reported an all-solid-state solar cell consisting of a highly structured heterojunction between a p- and n-type semiconductor with a absorber in between in which the p-semiconductor is CuSCN or CuI, the n-semiconductor is nano-porous titanium dioxide and the absorber is an organic dye.

Furthermore, in 1998 K. Tennakone et al. reported in Journal Physics A: Applied Physics, volume 31, pages 2326-2330, a nano-porous n-TiO₂/˜23 nm selenium film/p-CuCNS photovoltaic cell which generated a photocurrent of ˜3.0 mA/cm², a photovoltage of ˜600 mV at 800 W/m² simulated sunlight and a maximum energy conversion efficiency of ˜0.13%.

Vogel et al. in 1990 in Chemical Physics Letters, volume 174, page 241, reported the sensitization of highly porous TiO₂ with in-situ prepared quantum size CdS particles (40-200 Å), a photovoltage of 400 mV being achieved with visible light and high photon to current efficiencies of greater than 70% being achieved at 400 nm and an energy conversion efficiency of 6.0% under monochromatic illumination with k=460 nm. In 1994 Hoyer et al. reported in Applied Physics, volume 66, page 349, that the inner surface of a porous titanium dioxide film could be homogeneously covered with isolated quantum dots and Vogel et al. reported in Journal of Physical Chemistry, volume 98, pages 3183-3188, the sensitization of various nanoporous wide-bandgap semiconductors, specifically TiO₂, Nb₂O₅, Ta₂O5, SnO₂ and ZnO, with quantum-sized PbS, CdS, Ag₂S, Sb₂S₃ and Bi₂S₃ and the use of quantum dot-sensitized oxide semiconductors in liquid junction cells. The internal photocurrent quantum yield decreased with increasing particle diameter and decreased in the order TiO₂>ZnO>Nb₂O₅>SnO₂>Ta₂O₅.

EP-A 1 176 646 discloses a solid state p-n heterojunction comprising an electron conductor and a hole conductor, characterized in that if further comprises a sensitizing semiconductor, said sensitizing being located at an interface between said electron conductor and said hole conductor; and its application in a solid state sensitized photovolaic cell. In a preferred embodiment the sensitizing semiconductor is in the form of particles adsorbed at the surface of said electron conductor and in a further preferred embodiment the sensitizing semiconductor is in the form of quantum dots, which according to a particularly preferred embodiment are particles consisting of PbS, CdS, Bi₂S₃, Sb₂S₃, Ag₂S, InAs, CdTe, CdSe or HgTe or solid solutions of HgTe/CdTe or HgSe/CdSe. In another preferred embodiment the electron conductor is a ceramic made of finely divided large band gap metal oxide, with nanocrystalline TiO₂ being particularly preferred. EP-A 1 176 646 further includes an example for making a layered heterojunction in which SnO₂-coated glass was coated with a compact TiO₂ layer by spray pyrolysis, PbS quantum dots were deposited upon the TiO₂ layer, the hole conductor 2,2′,7,7′-tetrakis(N,N-di-p-methoxyphenyl-amine)9,9′-spirobifluorene (OMeTAD) was deposited on the quantum dots and a semitransparent gold back contact was evaporated on the OMeTAD layer.

There is a need for nano-particles with improved stability for spectrally sensitizing nano-porous metal oxide semiconductor layers.

### ASPECTS OF THE INVENTION

It is therefore an aspect of the present invention to provide improved spectral sensitization of nano-porous metal oxide semiconductors.

It is a further aspect of the present invention to provide a process for realizing improved spectral sensitization of nano-porous metal oxide semiconductors.

Further aspects and advantages of the invention will become apparent from the description hereinafter.

### SUMMARY OF THE INVENTION

It has been surprisingly found that spectral sensitization of nano-porous metal oxide semiconductor with a band-gap of greater than 2.9 eV on its internal and external surface with metal chalcogenide nano-particles is enhanced by the presence of a phosphoric acid or a phosphate.

Aspects of the present invention are realized by a nano-porous metal oxide semiconductor with a band-gap of greater than 2.9 eV in-situ spectrally sensitized on its internal and external surface with metal chalcogenide nano-particles with a band-gap of less than 2.9 eV containing at least one metal chalcogenide, wherein the nano-porous metal oxide further contains a phosphoric acid or a phosphate.

Aspects of the present invention are also realized by a process for in-situ spectral sensitization of nano-porous metal oxide semiconductor with a band-gap of greater than 2.9 eV on its internal and external surface with metal chalcogenide nano-particles with a band-gap of less than 2.9 eV, containing at least one metal chalcogenide, comprising a metal chalcogenide-forming cycle comprising the steps of: contacting nano-porous metal oxide with a solution of metal ions; contacting nano-porous metal oxide with a solution of chalcogenide ions; and subsequent to metal chalcogenide formation rinsing the nano-porous metal oxide with an aqueous solution containing a phosphoric acid or a phosphate.

Aspects of the present invention are also realized by a photovoltaic device containing the above-mentioned nano-porous metal oxide semiconductor.

Aspects of the present invention are also realized by a second photovoltaic device containing a nano-porous metal oxide semiconductor prepared by the above-mentioned process. Preferred embodiments are disclosed in the dependent claims.

### DETAILED DESCRIPTION OF THE INVENTION

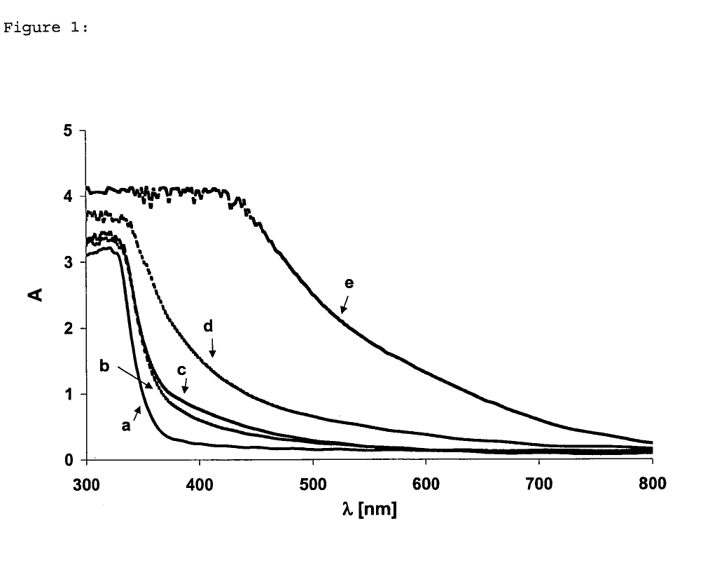

FIG. 1 represents the dependence of absorbance [A] upon wavelength [λ] in nm for: a, unsensitized nano-porous TiO₂ layer (. absorbance at 500 nm=0.15); b, nano-porous TiO₂ layer sensitized with PbS with one dipping cycle (absorbance at 500 nm=0.26); c, nano-porous TiO₂ layer sensitized with Bi₂S₃ with one dipping cycle (absorbance at 500 nm=0.28); d, nano-porous TiO₂ layer sensitized with PbS with three dipping cycles (absorbance at 500 nm=0.65); and e, nano-porous TiO₂ layer sensitized with Bi₂S₃ with three dipping cycles (absorbance at 500 nm=2.50).

### DEFINITIONS

The term nano-porous metal oxide semiconductor means a metal oxide semiconductor having pores with a size of 100 nm or less and having an internal surface area of at least 20 m²/g and not more than 300 m²/g.

The term chalcogenide means a binary compound containing a chalcogen and a more electropositive element or radical. A chalcogen is an element from group IV of the periodic table including oxygen, sulphur, selenium, tellurium and polonium.

The term “a mixture of two or more metal chalcogenides” includes a simple mixture thereof, mixed crystals thereof and doping of a metal chalcogenide by metal or chalcogenide replacement.

The term internal surface means the surface of pores inside a porous material.

The term in-situ spectrally sensitized means that the spectral sensitizer is formed where spectral sensitization is required.

The term aqueous for the purposes of the present invention means containing at least 60% by volume of water, preferably at least 80% by volume of water, and optionally containing water-miscible organic solvents such as alcohols e.g. methanol, ethanol, 2-propanol, butanol, iso-amyl alcohol, octanol, cetyl alcohol etc.; glycols e.g. ethylene glycol; glycerine; N-methyl pyrrolidone; methoxypropanol; and ketones e.g. 2-propanone and 2-butanone etc.

The term “support” means a “self-supporting material” so as to distinguish it from a “layer” which may be coated on a support, but which is itself not self-supporting. It also includes any treatment necessary for, or layer applied to aid, adhesion to the support.

The term continuous layer refers to a layer in a single plane covering the whole area of the support and not necessarily in direct contact with the support.

The term non-continuous layer refers to a layer in a single plane not covering the whole area of the support and not necessarily in direct contact with the support.

The term coating is used as a generic term including all means of applying a layer including all techniques for producing continuous layers, such as curtain coating, doctor-blade coating etc., and all techniques for producing non-continuous layers such as screen printing, ink jet printing, flexographic printing, and techniques for producing continuous layers

The abbreviation PEDOT represents poly(3,4-ethylenedioxythiophene).

The abbreviation PSS represents poly(styrene sulphonic acid) or poly(styrenesulphonate).

### Nano-Porous Metal Oxide Semiconductor

Aspects of the present invention are realized by a nano-porous metal oxide semiconductor with a band-gap of greater than 2.9 eV in-situ spectrally sensitized on its internal and external surface with metal chalcogenide nano-particles with a band-gap of less than 2.9 eV containing at least one metal chalcogenide, wherein the nano-porous metal oxide further contains a phosphoric acid or a phosphate.

According to a first embodiment of the nano-porous metal oxide semiconductor, according to the present invention, the metal oxide semiconductor is n-type.

According to a second embodiment of the nano-porous metal oxide, according to the present invention, the metal oxide is selected from the group consisting of titanium oxides, tin oxides, niobium oxides, tantalum oxides, tungsten oxides and zinc oxides.

According to a third embodiment of the nano-porous metal oxide semiconductor, according to the present invention, the nano-porous metal oxide semiconductor is titanium dioxide.

### Metal Chalcogenide

Aspects of the present invention are realized by a nano-porous metal oxide semiconductor with a band-gap of greater than 2.9 eV in-situ spectrally sensitized on its internal and external surface with metal chalcogenide nano-particles with a band-gap of less than 2.9 eV containing at least one metal chalcogenide, wherein the nano-porous metal oxide further contains a phosphoric acid or a phosphate.

According to a fourth embodiment of the nano-porous metal oxide, according to the present invention, the metal chalcogenide is a metal oxide, metal sulphide, metal selenide or a mixture of two or more thereof.

According to a fifth embodiment of the nano-porous metal oxide, according to the present invention, the metal chalcogenide is a metal sulphide or a mixture of two or more thereof.

According to a sixth embodiment of the nano-porous metal oxide, according to the present invention, the metal chalcogenide is selected from the group consisting of lead sulphide, bismuth sulphide, cadmium sulphide, silver sulphide, antimony sulphide, indium sulphide, copper sulphide, cadmium selenide, copper selenide, indium selenide, cadmium telluride or a mixture of two or more thereof.

### Phosphoric Acid or a Phosphate

Aspects of the present invention are realized by a nano-porous metal oxide with a band-gap of greater than 2.9 eV in-situ spectrally sensitized on its internal and external surface with metal chalcogenide nano-particles with a band-gap of less than 2.9 eV containing at least one metal chalcogenide, wherein the nano-porous metal oxide further contains a phosphoric acid or a phosphate.

According to a seventh embodiment of the nano-porous titanium, according to the present invention, the phosphoric acid is selected from the group consisting of orthophosphoric acid, phosphorous acid, hypophosphorous acid and polyphosphoric acids.

Polyphosphoric acids include diphosphoric acid, pyrophosphoric acid, triphosphoric acid, tetraphosphoric acid, metaphosphoric acid and “polyphosphoric acid”.

According to an eighth embodiment of the nano-porous titanium, according to the present invention, the phosphate is selected from the group consisting of orthophosphates, phosphates, phosphites, hypophosphites and polyphosphates.

Polyphosphates are linear polyphosphates, cyclic polyphosphates or mixtures thereof. Linear polyphosphates contain 2 to 15 phosphorus atoms and include pyrophosphates, dipolyphosphates, tripolyphosphates and tetrapolyphosphates. Cyclic polyphosphates contain 3 to 8 phosphorus atoms and include trimetaphosphates and tetrametaphosphates and metaphosphates.

Polyphosphoric acid may be prepared by heating H₃PO₄ with sufficient P₄O₁₀ (phosphoric anhydride) or by heating H₃PO₄ to remove water. A P₄O₁₀/H₂O mixture containing 72.74% P₄O₁₀ corresponds to pure H₃PO₄, but the usual commercial grades of the acid contain more water. As the P₄O₁₀ content H₄P₂O₇, pyrophosphoric acid, forms along with P₃ through P₈ polyphosphoric acids. Triphosphoric acid appears at 71.7% P₂O₅ (H₅P₃O₁₀) and tetraphosphoric acid (H₆P₄O₁₃) at about 75.5% P₂O₅. Such linear polyphosphoric acids have 2 to 15 phosphorus atoms, which each bear a strongly acidic OH group. In addition, the two terminal P atoms are each bonded to a weakly acidic OH group. Cyclic polyphosphoric acids or metaphosphoric acids, HₙPₙO₃ₙ, which are formed from low-molecular polyphosphoric acids by ring closure, have a comparatively small number of ring atoms (n=3-8). Each atom in the ring is bound to one strongly acidic OH group. High linear and cyclic polyphosphoric acids are present only at acid concentrations above 82% P₂O₅. Commercial phosphoric acid has a 82 to 85% by weight P₂O₅ content. It consists of about 55% tripolyphosphoric acid, the remainder being H₃PO₄ and other polyphosphoric acids.

A polyphosphoric acid suitable for use according to the present invention is a 84% (as P₂O₅) polyphosphoric acid supplied by ACROS (Cat. No. 19695-0025).

### Triazole or Diazole Compound

According to a ninth embodiment of the nano-porous metal oxide, according to the present invention, the nano-porous metal oxide further contains a triazole or diazole compound.

According to a tenth embodiment of the nano-porous metal oxide, according to the present invention, the nano-porous metal oxide further contains a tetraazaindene.

According to an eleventh embodiment of the nano-porous metal oxide, according to the present invention, the nano-porous metal oxide further contains 5-methyl-1,2,4-triazolo-(1,5-a)-pyrimidine-7-ol).

Suitable triazole or diazole compounds, according to the present invention, include:

| | Structure | |
|---|---|---|
| T1 | 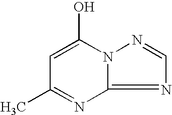 | 5-methyl-1,2,4- triazolo-(1,5- a)-pyrimidine 7-ol |
| T2 | 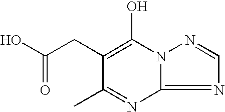 | |
| T3 | 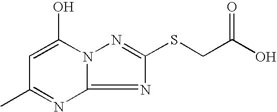 | |
| D1 | 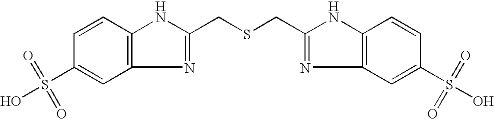 | |

### Process for In-Situ Spectral Sensitization of Nano-Porous Metal Oxide with Metal Chalcogenide Nano-Particles

Aspects of the present invention are also realized by a process for in-situ spectral sensitization of nano-porous metal oxide semiconductor with a band-gap of greater than 2.9 eV on its internal and external surface with metal chalcogenide nano-particles with a band-gap of less than 2.9 eV, containing at least one metal chalcogenide, comprising a metal chalcogenide-forming cycle comprising the steps of: contacting nano-porous metal oxide with a solution of metal ions; contacting nano-porous metal oxide with a solution of chalcogenide ions; and subsequent to metal chalcogenide formation rinsing the nano-porous metal oxide with an aqueous solution containing a phosphoric acid or a phosphate.

According to a first embodiment of the process, according to the present invention, the contact with a solution of metal ions occurs before the contact with a solution of chalcogenide ions.

According to a second embodiment of the process, according to the present invention, the metal chalcogenide-forming cycle is repeated.

According to a third embodiment of the process, according to the present invention, the solution of metal ions and/or the solution of chalcogenide ions further contains a triazole or diazole compound.

### Support

Supports for use according to the present invention include polymeric films, silicon, ceramics, oxides, glass, polymeric film reinforced glass, glass/plastic laminates, metal/plastic laminates, paper and laminated paper, optionally treated, provided with a subbing layer or other adhesion promoting means to aid adhesion to adjacent layers. Suitable polymeric films are poly(ethylene terephthalate), poly(ethylene naphthalate), polystyrene, polyethersulphone, polycarbonate, polyacrylate, polyamide, polyimides, cellulosetriacetate, polyolefins and poly(vinylchloride), optionally treated by corona discharge or glow discharge or provided with a subbing layer.

### Photovoltaic Devices

Aspects of the present invention are realized by a photovoltaic device comprising the porous metal oxide semiconductor, according to the present invention.

Aspects of the present invention are realized by a second photovoltaic device comprising a porous metal oxide semiconductor produced according to the process, according to the present invention.

According to a first embodiment of the photovoltaic device, according to the present invention, the photovoltaic device comprises a layer configuration.

According to a first embodiment of the second photovoltaic device, according to the present invention, the photovoltaic device comprises a layer configuration.

Photovoltaic devices incorporating the spectrally sensitized nano-porous metal oxide, according to the present invention, can be of two types: the regenerative type which converts light into electrical power leaving no net chemical change behind in which current-carrying electrons are transported to the anode and the external circuit and the holes are transported to the cathode where they are oxidized by the electrons from the external circuit and the photosynthetic type in which there are two redox systems one reacting with the holes at the surface of the semiconductor electrode and one reacting with the electrons entering the counter-electrode, for example, water is oxidized to oxygen at the semiconductor photoanode and reduced to hydrogen at the cathode. In the case of the regenerative type of photovoltaic cell, as exemplified by the Graetzel cell, the hole transporting medium may be a liquid electrolyte supporting a redox reaction, a gel electrolyte supporting a redox reaction, an organic hole transporting material, which may be a low molecular weight material such as 2,2′,7,7′-tetrakis(N,N-di-p-methoxyphenyl-amine)9,9′-spirobifluorene (OMeTAD) or triphenylamine compounds or a polymer such as PPV-derivatives, poly(N-vinylcarbazole) etc., or inorganic semiconductors such as CuI, CUSCN etc. The charge transporting process can be ionic as in the case of a liquid electrolyte or gel electrolyte or electronic as in the case of organic or inorganic hole transporting materials.

Such regenerative photovoltaic devices can have a variety of internal structures in conformity with the end use. Conceivable forms are roughly divided into two types: structures which receive light from both sides and those which receive light from one side. An example of the former is a structure made up of a transparently conductive layer e.g. an ITO-layer or a PEDOT/PSS-containing layer and a transparent counter electrode electrically conductive layer e.g. an ITO-layer or a PEDOT/PSS-containing layer having interposed therebetween a photosensitive layer and a charge transporting layer. Such devices preferably have their sides sealed with a polymer, an adhesive or other means to prevent deterioration or volatilization of the inside substances. The external circuit connected to the electrically-conductive substrate and the counter electrode via the respective leads is well-known.

Alternatively the spectrally sensitized nano-porous metal oxide, according to the present invention, can be incorporated in hybrid photovoltaic compositions such as described in 1991 by Graetzel et al. in Nature, volume 353, pages 737-740, in 1998 by U. Bach et al. [see Nature, volume 395, pages 583-585 (1998)] and in 2002 by W. U. Huynh et al. [see Science, volume 295, pages 2425-2427 (2002)]. In all these cases, at least one of the components (light absorber, electron transporter or hole transporter) is inorganic (e.g. nano-TiO₂ as electron transporter, CdSe as light absorber and electron transporter) and at least one of the components is organic (e.g. triphenylamine as hole transporter or poly(3-hexylthiophene) as hole transporter).

### INDUSTRIAL APPLICATION

Spectrally sensitized nano-porous metal oxide, according to the present invention, can be used in both regenerative and photosynthetic photovoltaic devices.

The invention is illustrated hereinafter by way of reference and invention photovoltaic devices. The percentages and ratios given in these examples are by weight unless otherwise indicated.

### EXAMPLE 1

### Preparation of Solutions Used in In-Situ Preparation of Nano-Sulphide Particles

Metal Solution 1:

Metal solution 1, a 0.6 M Bi³⁺-solution, was prepared by mixing 36 mL of deionized water, 6.2 mL of concentrated HNO₃ and 28.75 g of Bi(NO₃)₃.5H₂O, then adding a solution of 40 g triammonium citrate in 36 mL of deionized water and finally slowly adding 16 mL of a 50% NaOH-solution.

Metal Solution 2:

Metal solution 2, a 0.96 M Pb²⁺-solution, was prepared by dissolving 37.65 g of Pb(NO₃)₂ in 100 mL of deionized water.

Sulphide Solution 1:

Sulphide solution 1, a 0.1 M S²⁻ solution, was prepared by dissolving 0.78 g of Na₂S in 100 mL of deionized water.

Efficient adsorption of nano-sulphides on a nano-porous TiO₂ layer.

A glass substrate (FLACHGLAS AG) was ultrasonically cleaned in ethanol for 5 minutes and then dried. A layer of a nano-TiO2 dispersion (Ti-nanoxide HT Solaronix SA) was applied to the glass substrate using a doctor blade coater. This titanium dioxide-coated glass was heated to 450° C. for 30 minutes. This results in a highly transparent nano-porous TiO₂ layer. A dry layer thickness of 1.4 μm was obtained as verified by laserprofilometry (DEKTRAK™ profilometer), mechanically with a diamond-tipped probe (Perthometer) and interferometry.

After the sintering step, the titanium dioxide-coated glass plates were cooled to 150° C. by placing them on a hot plate at 150° C. for 10 minutes and then immediately dipped into the metal solution for 1 minute, then rinsed for 10 seconds with deionized water immediately followed by dipping for 1 minute in the sulphide solution and finally rinsing once more with deionized water for 10 seconds. In this dipping cycle nano-metal sulphides were deposited on the internal and external surface of the nano-porous titanium dioxide. The amount of adsorbed nano-metal sulphide particles could increased by carrying out multiple dipping cycles.

Absorption spectra between 200 and 800 nm were obtained using a Hewlett-Packard diode-array spectrophotometer HP 8452A. FIG. 1 shows the absorption spectra for pure TiO₂, TiO₂ with one cycle of Metal solution 1 (Bi³⁺) and sulphide solution 1; and TiO₂ with one cycle of Metal solution 2 (Pb²⁺) and sulphide solution 1. The absorption band was very broad and as a point of reference only the absorbance values at 500 nm are given in the examples below.

Dipping cycles were carried out with Metal solutions 1 and 2 and Sulphide solution 1 as given in Table 1 and the absorbances at 500 nm of the resulting in-situ formed nano-metal sulphides determined, see results in Table 1.

TABLE 1

| | Metal | | | |
|---|---|---|---|---|
| Experiment | solution | Metal sulphide | number of | Absorbance |
| nr. | used | formed | dipping cycles | at 500 nm* |
| 1 (comp) | 1 | Bi₂S₃ | 1 | 0.14 |
| 2 (comp) | 1 | Bi₂S₃ | 2 | 1.28 |
| 3 (comp) | 1 | Bi₂S₃ | 3 | 2.40 |
| 4 (comp) | 1 | Bi₂S₃ | 5 | >4 |
| 5 (comp) | 2 | PbS | 1 | 0.12 |
| 6 (comp) | 2 | PbS | 2 | 0.37 |
| 7 (comp) | 2 | PbS | 3 | 0.59 |
| 8 (comp) | 2 | PbS | 5 | 1.23 |
| 9 (comp) | 2 | PbS | 7 | 2.47 |

*corrected for the absorbance of TiO₂ at 500 nm (ca 0.15)

Multiple dipping led to higher absorbances.

### EXAMPLE 2

### Stabilization of Bi₂S₃ Nano-Particles with Polyphosphoric Acid

Experiments 10 to 13 were carried out as described for Example 1, except that the final rinsing was performed with deionized water, with a 2% solution of polyphosphoric acid in deionized water, with a 70% solution of polyphosphoric acid in deionized water or with a 2% solution of hexametaphosphate in deionized water, as given in Table 2.

After the rinsing, the absorption spectra of the Bi₂S₃ nanoparticles were measured as described for Experiments 1 to 9: immediately, after open exposure to room lighting conditions for 4 hours, and after open exposure to room lighting conditions for 5 days. The absorbances at 500 nm are given in Table 2.

TABLE 2

| | Phosphoric acid/phosphate | | | |
|---|---|---|---|---|
| Experiment | present during final rinsing | Absorbance at 500 nm* | | |
| nr. | step | Fresh | After 4 h | After 5 d |
| 10 (comp) | No | 0.15 | 0.01 | 0.01 |
| 11 (inv) | Polyphosphoric acid (2%) | 0.15 | 0.14 | 0.04 |
| 12 (inv) | Polyphosphoric acid (70%) | 0.15 | 0.15 | 0.14 |
| 13 (inv) | Hexametaphosphate (2%) | 0.15 | 0.14 | 0.02 |

*corrected for the absorbance of TiO₂ at 500 nm (ca 0.15)

From the results in Table 2, the Bi₂S₃ nano-particles were clearly stabilized on the TiO₂-surface by the presence of a phosphoric acid or phosphate.

The present invention may include any feature or combination of features disclosed herein either implicitly or explicitly or any generalisation thereof irrespective of whether it relates to the presently claimed invention. Having described in detail preferred embodiments of the current invention, it will now be apparent to those skilled in the art that numerous modifications can be made therein without departing from the scope of the invention as defined in the following claims.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and similar referents in the context of describing the invention (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Of course, variations of those preferred embodiments will become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

I claim:

1. A nano-porous metal oxide semiconductor with a band-gap of greater than 2.9 eV in-situ spectrally sensitized on its internal and external surface with metal chalcogenide nanoparticles with a band-gap of less than 2.9 eV containing at least one metal chalcogenide, wherein said nano-porous metal oxide further contains a phosphoric acid or a phosphate.

2. Nano-porous metal oxide according to claim 1, wherein said metal oxide is selected from the group consisting of titanium oxides, tin oxides, niobium oxides, tantalum oxides and zinc oxides.

3. Nano-porous metal oxide according to claim 1, wherein said nanoporous metal oxide further contains a triazole or diazole compound.

4. A process for in-situ spectral sensitization of nano-porous metal oxide semiconductor with a band-gap of greater than 2.9 eV on its internal and external surface with metal chalcogenide nano-particles with a band-gap of less than 2.9 eV, containing at least one metal chalcogenide, comprising a metal chalcogenide-forming cycle comprising the steps of: contacting nano-porous metal oxide with a solution of metal ions; contacting nano-porous metal oxide with a solution of chalcogenide ions; and subsequent to metal chalcogenide formation rinsing said nano-porous metal oxide with an aqueous solution containing a phosphoric acid or a phosphate.

5. Process according to claim 4, wherein said contact with a solution of metal ions occurs before said contact with a solution of chalcogenide ions.

6. Process according to claim 4, wherein said metal chalcogenide-forming cycle is repeated.

7. Process according to claim 4, wherein said solution of metal ions contains a triazole or diazole compound.

8. Process according to claim 4, wherein said solution of metal ions and said solution of chalcogenide ions contains a triazole or diazole compound.

9. Process according to claim 4, wherein said solution of chalcogenide ions contains a triazole or diazole compound.

10. Process according to claim 4, wherein said nano-porous metal oxide is selected from the group consisting of titanium oxides, tin oxides, niobium oxides, tantalum oxides and zinc oxides.

11. Process according to claim 4, wherein said nano-porous metal oxide further contains a triazole or diazole compound.

12. A photovoltaic device containing a nano-porous metal oxide semiconductor with a band-gap of greater than 2.9 eV in-situ spectrally sensitized on its internal and external surface with metal chalcogenide nano-particles with a band-gap of less than 2.9 eV containing at least one metal chalcogenide, wherein said nano-porous metal oxide further contains a phosphoric acid or a phosphate.

13. Photovoltaic device according to claim 12, wherein said nanoporous metal oxide is selected from the group consisting of titanium oxides, tin oxides, niobium oxides, tantalum oxides and zinc oxides.

14. Photovoltaic device according to claim 12, wherein said nanoporous metal oxide further contains a triazole or diazole compound.

15. A second photovoltaic device containing a nano-porous metal oxide semiconductor with a band-gap of greater than 2.9 eV in-situ spectrally sensitized on its internal and external surface with metal chalcogenide nano-particles with a band-gap of less than 2.9 eV containing at least one metal chalcogenide prepared according to a process for in-situ spectral sensitization of nano-porous metal oxide semiconductor comprising a metal chalcogenide-forming cycle comprising the steps of: contacting nano-porous metal oxide with a solution of metal ions; contacting nano-porous metal oxide with a solution of chalcogenide ions; and subsequent to metal chalcogenide formation rinsing said nano-porous metal oxide with an aqueous solution containing a phosphoric acid or a phosphate.

16. Second photovoltaic device according to claim 15, wherein said contact with a solution of metal ions occurs before said contact with a solution of chalcogenide ions.

17. Second photovoltaic device according to claim 15, wherein said metal chalcogenide-forming cycle is repeated.

18. Second photovoltaic device according to claim 15, wherein said solution of metal ions contains a triazole or diazole compound.

19. Second photovoltaic device according to claim 15, wherein said solution of metal ions and said solution of chalcogenide ions contains a triazole or diazole compound.

20. Second photovoltaic device according to claim 15, wherein said solution of chalcogenide ions contains a triazole or diazole compound.

21. Second photovoltaic device according to claim 15, wherein said nano-porous metal oxide is selected from the group consisting of titanium oxides, tin oxides, niobium oxides, tantalum oxides and zinc oxides.

22. Photovoltaic device according to claim 15, wherein said nanoporous metal oxide further contains a triazole or diazole compound.
